(19) United States
(12) Patent Application Publication
(10) Pub. No.: US 2016/0141152 A1
(43) Pub. Date: May 19, 2016

(54) METHOD AND SYSTEM FOR MODIFYING A SUBSTRATE USING A PLASMA

(71) Applicant: INNOVATION ULSTER LIMITED, Newtownabbey, Antrim (GB)

(72) Inventors: Cormac Patrick Byrne, Newry, Down (GB); Brian Joseph Meenan, Lisburn, Antrim (GB); Kyle George Doherty, Belfast, Antrim (GB)

(21) Appl. No.: 14/903,041

(22) PCT Filed: Jul. 3, 2014
(86) PCT No.: PCT/EP2014/064198

§ 371 Date: Jan. 5, 2016

(30) Foreign Application Priority Data
Jul. 5, 2013 (GB) 1312075.3

(51) Int. Cl. H01J 37/32

(52) U.S. Cl. CPC H01J 37/32715; H01J 37/32568; H01J 2237/3321; H01J 2237/3341; H01J 2237/336; H01J 2237/3382

(57) ABSTRACT

A method and system of modifying a substrate using a plasma are described comprising providing a first electrode and a second electrode; arranging the substrate such that a portion of the substrate is between the electrodes; supplying a voltage to at least one of the electrodes so as to create a plasma discharge between the electrodes which contacts at least said portion of the substrate, moving either the substrate and/or said second electrode such that said substrate and said second electrode are being linearly displaced relative to each other along an axis of linear displacement during said movement; and wherein said second electrode is arranged relative to said axis of linear displacement such that said linear movement causes a first section of the portion of substrate to have a greater residence time between the electrodes during said linear displacement than a second section of said portion of the substrate. A method and system of modifying a substrate using a plasma is also described comprising providing a first electrode and a second electrode; arranging the substrate such that a portion of the substrate is between the electrodes; supplying a voltage to at least one of the electrodes so as to create a plasma discharge between the electrodes which contacts at least said portion of the substrate, moving either the substrate and/or said second electrode such that said substrate and said second electrode are being linearly displaced relative to each other along an axis of linear displacement during said movement; and further comprising the step of rotating either the substrate or said second electrode about an axis of rotation during said relative linear displacement along said axis, so that a first section of the portion of substrate has a greater residence time between the electrodes than a second section of said portion of substrate.

### FIELD OF THE INVENTION

The present invention relates to a process and system for modifying the surface of a substrate using a plasma discharge process. More particularly, the present invention relates to a process and system for the scale up of plasma induced surface functionality.

### BACKGROUND OF THE INVENTION

It is known that substrates with specific predetermined surface properties can influence biological and related events and testing thereof. For example, the behaviour and response of cells, proteins and biomolecules of various kinds, including those associated with the immune system can be influenced by chemical and structural characteristics and properties. Control of such events may be useful in areas such as medical implants, oncology, stem cell culture, deep vein thrombosis, drug delivery, biomarker identification, etc. Typically, substrates used in any form of diagnosis or treatment have inherent surface properties that will facilitate a form of action with a biological environment or test platform. In order to optimise the interaction between the surface of a substrate and the cells or biomolecules concerned its surface may be treated in some manner. However, in many cases such treatment procedures are lengthy and resource intensive.

The present invention provides an improved method and system for treating a substrate which may be useful in the above field of technology and in other fields of technology such as the nanotechnology sector, e.g. in carbon nanomaterials, biosensors, fuel cells, batteries, nanochemistry, photocatalysis, solar cells, nanoelectronics, and nanoparticles for drug delivery.

The invention can be used to develop a wide range of functional properties, including physical, chemical, electrical, electronic, magnetic, mechanical, wear-resistant and corrosion-resistant properties at the required substrate surfaces. It is also possible to use the process described herein to form coatings of new materials, graded deposits, multi-component deposits, etc. Therefore, the present invention will be of interest to many industries such as automotive, aerospace, missile, power, electronic, biomedical, textile, petroleum, petrochemical, chemical, steel, cement, machine tools and construction industries.

WO 2012/107723A1 describes a plasma based surface augmentation method. The method comprises providing a first electrode and second electrode and arranging a substrate such that only a portion of the substrate is between the electrodes, and rotating either the substrate or at least one of the electrodes about an axis so as to cause different portions of the substrate to pass between the electrodes during rotation.

### SUMMARY OF THE INVENTION

From a first aspect, the present invention may comprise a method of modifying a substrate using a plasma, comprising: providing a first electrode and a second electrode; arranging the substrate such that a portion of the substrate is between the electrodes; supplying a voltage to at least one of the electrodes so as to create a plasma discharge between the electrodes which contacts at least said portion of the substrate, moving either the substrate and/or said second electrode such that said substrate and said second electrode are being linearly displaced relative to each other along an axis of linear displacement during said movement; and wherein said second electrode is arranged relative to said axis of linear displacement such that said linear movement causes a first section of the portion of substrate to have a greater residence time between the electrodes during said linear displacement than a second section of said portion of the substrate.

The present invention may also comprise a system for modifying a substrate using a plasma, comprising: a first electrode and a second electrode; a mechanism for supporting at least a first portion of a substrate to be treated between said first and second electrodes; means for supplying a voltage to at least one of the electrodes so as to create a plasma discharge between the second electrode and the substrate, means configured to move the substrate and/or said second electrode so that said substrate and said second electrode are linearly displaced relative to each other along an axis of displacement during said movement, said second electrode being positioned relative to said axis of displacement such that said linear movement causes a first section of the portion of substrate to have a greater residence time between the electrodes during said linear displacement than a second section of said portion of the substrate.

From a further aspect, the present invention may comprise a method of modifying a substrate using a plasma, comprising: providing a first electrode and a second electrode; arranging the substrate such that a portion of the substrate is between the electrodes; supplying a voltage to at least one of the electrodes so as to create a plasma discharge between the electrodes which contacts at least said portion of the substrate, moving either the substrate and/or said second electrode such that said substrate and said second electrode are being linearly displaced relative to each other along an axis of linear displacement during said movement; and further comprising the step of rotating either the substrate or said second electrode about an axis of rotation during said relative linear displacement along said axis, so that a first section of the portion of substrate has a greater residence time between the electrodes than a second section of said portion of substrate.

The present invention may also comprise a system for modifying a substrate using a plasma, comprising: a first electrode and a second electrode; a mechanism for supporting at least a first portion of a substrate to be treated between said first and second electrodes; means for supplying a gas between at least the second electrode and the substrate, means for supplying a voltage to at least one of the electrodes so as to create a plasma discharge between the second electrode and the substrate, means configured to move the substrate and/or said second electrode so that said substrate and said second electrode are linearly displaced relative to each other along an axis of displacement during movement, and further comprising means for rotating either the substrate or at least one of the electrodes about an axis of rotation during said relative linear movement, so that a first section of the portion of substrate has a greater residence time between the electrodes than a second section of said portion of substrate.

In some embodiments, the system second electrode may have a shape and the second electrode may be arranged relative to said axis of linear displacement such that said shape causes said first section of the portion of substrate to have said greater residence time between the electrodes during said linear displacement than said second section of said portion of the substrate.

In some embodiments, the second electrode may have a shape and may be arranged relative to said axis of linear displacement such that said shape causes said first section of the portion of substrate to extend for a greater distance between said first and second electrodes along said axis of displacement than said second section of said portion of substrate.

In some embodiments, the second electrode may comprise a first side with a first shaped profile, and the substrate may be positioned between said electrodes so that said first shaped profile is facing said portion of substrate positioned between the electrodes.

In some embodiments, the second electrode may be an elongated electrode.

In some embodiments, the second electrode may have a non-linear and/or non-uniform profile.

The second electrode may further have a profile that is wedge-shaped and/or tapered, or it may have a curved profile.

In some embodiments, at least a portion of the first electrode may extend in a first plane and at least a portion of the second electrode may extend in a second plane and the first and second planes may be substantially parallel to each other and thereby define a gap between these substantially parallel portions. The substrate may pass through this gap during said linear movement of said substrate and/or said second electrode.

In some embodiments, an electrode assembly comprising a plurality of said second electrodes may be provided and this may be rotated about an axis of rotation. In further embodiments, a plurality of such electrode assemblies may be provided.

In some embodiments, the substrate may be moved linearly at a first speed along said axis of displacement and said second electrode ma be moved at a second speed along said axis of displacement, said first and second speeds being different to each other, so that said portion of said substrate passes along said axis between the electrodes. The second speed may be greater than the first speed.

The first electrode may comprise a platen and the substrate may be provided on the platen.

A plurality of such platens may also be provided and the substrate may be provided on said plurality of platens, such that movement of said plurality of platens having said substrate provided thereon causes movement of said substrate and said linear displacement of said substrate and said second electrode relative to each other.

The platen may comprise a flexible platen and the flexible platen, having said substrate provided thereon, may be moved along said axis of displacement so that said portion of said substrate passes along said axis of movement between the electrodes.

The flexible platen or plurality of platens may be provided on a platen carousel and the step of linearly displacing said substrate and said second electrode relative to each other may comprise rotating said carousel.

In some embodiments, the platen carousel may rotate in a plane that extends along the axis of displacement and also perpendicular to the plane of the substrate and/or platen, to thereby move said plurality of platens linearly along said axis of displacement.

In some embodiments, the substrate may extend from a first reel to a second reel and the substrate and the second electrode may be linearly displaced relative to each other by rotating the first and/or second reel to thereby move the substrate along the axis of displacement.

In some embodiments, the second electrode may be mounted on an electrode carousel and the substrate and the second electrode may be linearly displaced relative to each other by rotating the electrode carousel so that the second electrode moves along said axis of displacement.

In some embodiments, the electrode carousel may rotate in a plane that extends along the axis of displacement and also perpendicular to the plane of the substrate and/or platen, to thereby move said second electrode along said axis of displacement.

In some embodiments, the electrode carousel may rotate in a plane that extends parallel to the plane of the substrate and/or platen, to thereby move said second electrode along said axis of displacement.

In some embodiments, the second electrode may comprise a wire electrode, a tubular electrode or a rod electrode and/the first electrode and/or second electrode may be covered in an electrical insulator.

In some embodiments, a potential difference or a current may be applied to the electrodes so as to generate the plasma therebetween, and the magnitude of the current or potential difference may be varied with time.

In some embodiments, a potential difference or a current may be repeatedly applied to the electrodes so as to generate the plasma therebetween, and the frequency of application of the current or potential difference may be varied with time.

The distance between the first and second electrodes may be dynamically varied with time.

In some embodiments, one or more type of gas may be supplied to the region between the electrodes whilst the plasma is being generated.

In some embodiments, one or more types of gas may comprise or carry at least one type of chemical which modifies the substrate when the plasma is being generated.

In some embodiments, a plurality of different types of gases may be caused to flow into the region at different flow rates.

In some embodiments, a gas distributor may be provided for supplying one or more types of gas to the region between the electrodes in a non-uniform manner.

The one or more types of gas may be provided at a plurality of loci between the electrodes.

The gas distributor may further comprise an elongated conduit having a plurality of apertures arranged along its length and located such that the one or more gas exits the conduit through the apertures and may be delivered to the region between the first and second electrodes.

In some embodiments, the second electrode may comprise the gas distributor.

In some embodiments, the second electrode may be an elongated tube having apertures.

The flow rate of one or more types of gas into the region between the electrodes may be varied across the substrate or the flow rate through different apertures in the gas distributor may be varied.

The electrodes and substrate may also be located in a chamber.

In some embodiments, the plasma treatment may alter the surface chemistry, topography, or morphology of the substrate surface, preferably by different amounts in different areas of the substrate.

The plasma may modify the substrate by one or more of the following processes: modifying the substrate surface to include chemical functionalities; depositing monomers or oligomers on the surface; grafting monomers or oligomers on the surface; polymerising monomers or oligomers on the surface; or changing the surface roughness of the substrate.

In some embodiments, the first and/or second electrode may be replenished after having been subjected to said plasma.

In some embodiments, a plurality of said first electrodes and/or a plurality of said second electrodes may be provided such that different separate regions of said substrate pass between the first and second electrodes simultaneously.

In some embodiments, the surface of said first or second electrode, or the surface of a dielectric material covering said first or second electrode, may have a chemical or topological pattern thereon.

In some embodiments, the plasma may occur at or about atmospheric pressure.

In some embodiments, the plasma may be generated by a dielectric barrier discharge process.

In some embodiments, the first and second electrodes may be arranged inside a chamber or enclosure.

In some embodiments, the gas may be supplied non-uniformly across the surface of the substrate.

In some embodiments, the gas may be supplied to the region between the electrode and the substrate through said plurality of apertures.

In some embodiments, the gas may have different flow rates through different apertures.

In some embodiments, at least one of the electrodes may have a conduit and one or more apertures extending from the conduit to the outside of the electrode and said gas may be supplied through the conduit so that it flows out of the at least one electrode through said apertures.

In some embodiments, biomolecules may be deposited or immobilized on the substrate.

In some embodiments, the method may comprise the subsequent step of vacuum forming the modified substrate to provide a 3-dimensional surface form.

In some embodiments, the method may further comprise processing the substrate prior to exposing it to said plasma, said processing being by one or more of the following techniques: embossing, vacuum forming, lithography, injection moulding, sputtering, chemical treatment (e.g. using silane derivatives), laser ablation, dip coating, spin coating, deposition, spraying, coating, ion beam etching, punching, cutting, mounting, adhering, welding, mechanically fixing or housing in substrate carriers.

In some embodiments, the method may further comprise processing the substrate after having exposed it to said plasma, said processing being by one or more of the following techniques: embossing, vacuum forming, lithography, injection moulding, sputtering, chemical treatment (e.g. using silane derivatives), biomaterial deposition, laser ablation, dip coating, spin coating, deposition, spraying, coating, ion beam etching, punching, cutting, mounting, adhering, welding, mechanically fixing or housing in substrate carriers.

### BRIEF DESCRIPTION OF THE DRAWINGS

Various embodiments of the present invention will now be described, by way of example only, and with reference to the drawings, in which:

FIG. 1 shows a top view of an electrode arrangement according to one embodiment of the invention

FIG. 2 shows a side view of the embodiment of FIG. 1.

FIG. 3 shows a top view of an embodiment of the invention, showing the integration of a gas distributor arranged with the second electrode.

FIG. 4 shows a side view of the embodiment of FIG. 3

FIGS. 5a and b show a top view of further embodiments of the invention wherein the second electrode has a varying cross section.

FIG. 6 shows a side view of an example of an embodiment of a variable height adjustment feature as part of the assembly.

FIG. 7 shows a top view of a dielectric and/or electrode surface material that comprises a patterned surface.

FIG. 8 shows a side view of an embodiment of the invention wherein the ground electrode and the substrate move in synergy whilst the working electrode moves at a rate different to this.

FIG. 9 shows a top view of an embodiment of the invention wherein the working electrodes are mounted on a carousel that rotates the working electrodes about an axis so that they move in a plane that extends generally parallel to the plane of the substrate positioned underneath

FIG. 10 shows a side view of an embodiment of the invention wherein the working electrodes are mounted on a carousel that rotates the working electrodes about an axis so that they move along the axis of displacement and in a plane that extends from the axis of displacement and generally perpendicular to the plane of the substrate positioned underneath.

FIG. 11 shows a side view of an embodiment of the invention wherein the substrate is mounted and transferred through the process in a start/stop fashion using a form of a reel to reel mechanism.

FIG. 12 shows a side view of an example of an embodiment of the assembly where the substrate to be treated with gradient surface functionality is mounted and transferred through the process in a continuous fashion using a form of a reel to reel mechanism.

FIG. 13 shows a side view of an example of an embodiment of the assembly where the ground electrode takes the form of many inflexible platen type elements mounted on a carousel that cycles so as to match the speed of transition of the substrate between the electrodes.

FIG. 14 shows a side view of an example of the embodiment shown in FIG. 13 where the working electrode and ground electrodes are moved simultaneously on carousels.

FIG. 15 shows a side view of an embodiment of the invention wherein the ground electrode is flexible in nature and may be continuously cycled through the process.

FIG. 16 shows a top view of an embodiment of the invention wherein working electrode assemblies are mounted on a carousel that rotates the working electrodes about an axis so that they move in a plane that extends generally perpendicular to the plane of the substrate positioned underneath and wherein each of the working electrode assemblies further rotates about its own individual line.

FIG. 17 shows a side view of a chamber that can be used with any of the embodiments described herein.

FIG. 18 shows a side view of an embodiment of the invention wherein the elongated working electrode is replenished continuously or on a start/stop basis.

FIG. 19 shows the water contact angle analysis of a modified polypropylene substrate.

### SPECIFIC DESCRIPTION

The processes and systems described herein are for modifying the surface of a substrate using a plasma discharge process and provide a number of ways to effectively control substrate modification.

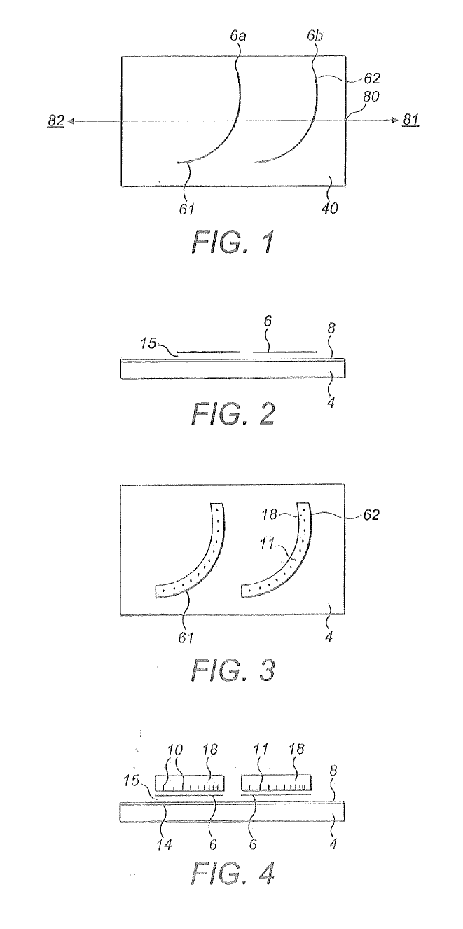

As shown in FIGS. 1 to 5, the present invention may comprise a first electrode, 4, and at least one second electrode, 6. The first electrode, 4, and the second electrode(s), 6, may be positioned relative to each other to provide a gap or space, 15, therebetween, as shown in FIGS. 1 and 3. In the embodiments shown in FIGS. 1 to 5, the first electrode, 4, can be seen as being positioned beneath the second electrode(s), 6, to provide this gap, 15. A substrate, 8, the surface of which is to be modified using a plasma discharge process, is positioned between these two electrodes and within this gap, 15.

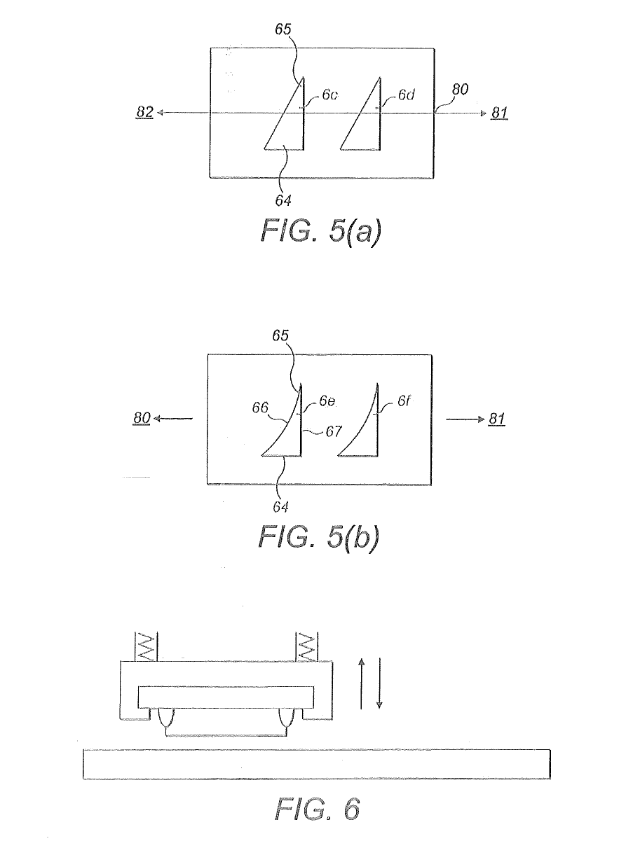

In the embodiment shown in FIGS. 1 to 5, the first electrode, 4, acts as a ground electrode, whereas the second electrode acts as a working electrode, 6. In some embodiments, only one working electrode may be used, however, in the embodiments shown in FIGS. 1 to 5, the system is shown comprising a plurality of second, or working, electrodes, 6a, 6b. For example, FIG. 3 shows a top view of the embodiment of figure wherein the electrode arrangement comprises two of these working electrodes, 6a, 6b. FIGS. 5a and b also show different systems which also each comprise two working electrodes, 6c, 6d, 6e, 6f. Additional working electrodes may also be used.

The working electrodes, 6, (which in some embodiments may be a wire electrode), are therefore arranged at a distance above the first electrode, 4, to provide this gap, or space, 15, therebetween. In this embodiment, the first, or ground, electrode, 4, comprises a platen, 4, that is movable linearly, along a line, 80, back and forth in first, 81, and second, 82, opposite directions along this axis of movement, 80. The substrate, 8 is mounted, (in the embodiments shown in FIGS. 1 to 4, directly) onto the upper surface of the platen, 4 so that it is positioned in the gap between the two electrodes. In other examples the substrate may be mounted indirectly and/or a dielectric, 7, may be used.

In the embodiments shown in FIGS. 1 to 5, the substrate is provided directly on the uppermost surface of the platen, (i.e. that which is facing the second electrode(s), 6) and linear movement of the platen, 4, along the axis of movement, 80, also results in linear movement of the substrate, 8, provided thereon. Due to this movement of the substrate, the substrate and the second electrode are therefore linearly displaced relative to each other along the axis of movement, i.e. axis of linear displacement, 80, In these embodiments, the working electrodes, 6, remain stationary, however, in other embodiments, they may also move, as described later.

A gas distributor, 18, may further be provided to supply gas to the space, 15, between the two electrode, 4, 6, to thereby generate a plasma discharge between the electrodes and a high voltage is applied to at least one of the electrodes so as to create a plasma discharge between the electrodes. This plasma discharge contacts and modifies at least the portion of the substrate, 8, that is passing between the electrodes during the linear movement of the substrate. This region in which the discharge occurs may be accurately controlled to provide variation in discharge power, distribution and number of treatment cycles.

For example, in some embodiments of the present invention, the gas distributor, 18, may provide a non-uniform gas distribution as a means of creating enhanced or otherwise unique dielectric barrier discharge operating conditions that can engender well defined localised changes in surface chemistry and/or topography of the substrate.

It is also possible to combine a unique form of distributed gas (air or other gas) delivery to the gap between the electrodes, 15 (hereinafter referred to as the electrode gap) and movement of the substrate, 8, and/or electrode(s), 6, under specific speeds and conditions. In essence, the gas (air or other gas) may be presented to the working electrodes, 6, via exit points, 11, that produce loci of flow.

FIG. 3 shows a top view of the embodiment of FIG. 1, wherein a gas distributor is integrated into the working electrodes, 6a, 6b. FIG. 4 shows a side view of the system. In FIGS. 3 and 4, a gas distributor, 18, may be arranged above the working electrode, 6, which includes a plurality of channels, 10, which lead to these exit points, 11, for supplying gas at discrete loci. A form of gas distributor comprising a hollow tube for carrying the gas with a plurality of apertures in the tube is described in WO 2012/107723 A1. The apertures deliver the gas to the substrate surface in the plasma discharge region at the loci adjacent to the position of the holes, thus providing localised gas flow at a plurality of points along the substrate surface. This arrangement permits the combined effects of energy dose and gas flow/concentration to be exercised in the same plane.

In some embodiments, the gas distributor may be adapted to provide a varying profile of types and amounts of gases, to provide a general and/or localised variation of the gas condition in proximity to the electrode. This arrangement changes the plasma conditions across the length of the electrode in a manner that provides for associated localised variations in the excited species created in these regions and hence varies the degree to which the surface modification occurs in regions proximal to these points. The origin and direction of the gas flow may be adjusted during treatment or between treatments to provide for additional variation in plasma conditions during a treatment or in different treatment situations.

In some embodiments, the flow of a gas or gas mixtures into the discharge region is controlled as described in WO 2012/107723 A1. The gas flow may be controlled using mass flow controllers. Each mass flow controller operates in a different flow range (for example up to 20 L/min, 5 L/min, 0.5 L/min, and 0.01 L/min) in order to provide for accurately controlled flow levels and therefore enables delivery of predetermined percentage concentrations of each gas in the final mixture. These mass flow controllers are connected via input lines to the discharge chamber. The mass flow controllers may be operated manually using a suitable control unit or automatically via an appropriate software routine.

In some embodiments four mass flow controllers are controlled by such control units. The line entering each mass flow controller has four solenoid valves controlled via switches. These may also be controlled via computer software. This allows rapid switching of input gases to each of the mass flow controllers and thereby provides the functionality to produce gas mixtures across a very large concentration range. The gas is channeled to flow directly over the position of the working wire electrode but, can also be directed to purge the chamber. With appropriate gas mixtures aglow discharge may be produced. The types of gases that can be used as well as combinations and ratios thereof are largely unlimited due to the use of a stainless steel and polytetrafluoroethylene (PTFE) based flow control design. Additionally, many liquids in vapour form or solids in aerosol form may be carried to the discharge region using the same flow system using evaporation cells and carrier gases as necessary. This may include, but is not limited to, chemicals such as silanes, allylamine and other functional chemicals, monomers or oligomers (such as polyethylene glycol) suited to deposition and/or grafting or polymerisation.

In some embodiments, the system and method may be used in conjunction with a chamber, (although this is not necessary) and in a further embodiment the gas flow conditions can be controlled to allow for blanketing of the entire surface of the platen in order to provide a barrier between the substrate and other chamber gases. In this configuration the requirement for chamber purging prior to sample treatment may be negated.

Further working electrodes, 6, may be fixed over the platen surface, 4, in order to allow discharges that operate with similar or different electrical conditions (e.g. frequency, voltage, current) to augment substrate surfaces as part of the overall substrate treatment regime.

The working electrode, 6, shown in FIGS. 1 to 4 is a wire electrode, however, this may be replaced by a porous electrode configuration capable of providing for the delivery of gas through this electrode directly to the plasma region. In less preferred embodiments, the electrode(s), 6, above the platen, 4, may take the form of a ball-tipped wire, a quartz tube or other electrodes.

The electrode gap change may or may not be distinct from the gas gap (between gas distributor and platen). Additionally, in tandem or as a separate function, an alternative mechanism can be used to adjust the voltage signal used to set the power level (by changing the voltage across the discharge gap) in a manner that varies this dynamically during processing.

The adjustment of power and/or electrode gap parameters, in synchronisation or otherwise, affects the subsequent distribution and specific intensity of treatment zones. For example, at smaller electrode gaps the microfilaments that comprise the discharge region may be greater in number and distributed within a smaller area producing a more homogeneous surface treatment. At larger gaps the filaments may be less in number, act over a larger region and carry more power per filament therefore producing a slightly less homogeneous surface treatment.

For high power levels the region of treatment and power per microfilament will be higher. Not surprisingly, due to varying chemical bond energies, the relative concentrations of surface chemical functionalities (not just elemental composition) produced on the surface will be highly dependent on the energies dissipated in the discharge. As one example, in nitrogen, ammonia and similar type treatments, primary, secondary, and tertiary ammonium species along with pyridinium, imidazolium and similar components may functionalise the substrate surface. Therefore, by use of a combination of operating parameters, a substrate can be treated with a range of intricate chemistries in a one-step process.

The discharge power may be continuously or discontinuously changed over time throughout a specific region or in a number of different regions. The methods by which gas is made to flow through the discharge region may also be adapted to provide both gradual gradients of flow across the substrate or to create step changes in flow at specified locations. The gas distributor may further be designed in such as way as to provide for flows of different types of gases in close proximity to each other.

The variations in electrode gap and power can alternatively be achieved in a manner similar to the effects obtained above by using any form of electrode configuration conducive to delivering the effects of DBD processing, e.g. by using gearing and cams connected to the electrode drive system in a linear or reel to reel configuration. This could be considered as an additional form of this invention.

Although in the embodiment shown in FIGS. 1 to 4, the linear displacement of the substrate and the second electrode relative to each other is achieved using working electrodes that remain stationary while the substrate moves linearly relative to the electrodes, in other examples, the platen, and therefore, substrate, may alternatively be kept stationary, and the working electrodes may be moved linearly relative to the substrate, 8. In further examples, only the substrate, 8, may be moved along the line, 80, between the two electrodes, both of which remain stationary. In further embodiments (described later) this may also even involve moving both the substrate, 8, and the second electrode(s) in the same linear direction, 81, albeit at different speeds to each other (thereby providing relative movement between the substrate and the second electrode). In use, the substrate, 8, and/or the second electrode(s), 6, may therefore be described as being moved or displaced linearly relative to each other so that a portion of the substrate, 8, that is positioned between the first and second electrodes moves linearly along the axis of movement or displacement, 80, relative to at least the second electrode, 8.

As seen in FIGS. 1 to 5, in some embodiments of the present invention, the second electrode (or plurality of second electrodes, 6a, 6b) has a non-linear and/or non-uniform profile, or cross-section, that in use, faces the substrate, 8, and ground electrode, 4, positioned underneath. In the particular embodiment shown in FIGS. 1 to 4, the second electrodes have an elongated curved profile, although other shaped profiles could be used. For example, FIG. 5 shows a top view of an alternative electrode arrangement wherein one or more working electrodes, 6c, 6d, 6e, 6f, are used which have different ‘wedge’ shaped cross sections, or profiles.

In use, the second electrode(s) may be positioned relative to the substrate and the axis of linear displacement so that the cross sectional profile of the electrode(s) is facing the portion of the surface of the substrate to be treated. As shown in FIGS. 1, 3 and 5, the second electrode, 6, may further be positioned relative to the substrate, 8, and more particularly to the direction of movement, 81, of the substrate, so that the non-linear and/or non-uniform profile results in a first portion of the substrate that is passing between the electrodes having a greater residence time between the electrodes than a second portion of the substrate that is also passing between the electrodes.

In the examples shown in FIGS. 1 to 4, this is achieved due to the fact that the second electrode(s), 6a, 6b, has been positioned relative to the substrate, 8, and relative to the axis of movement or displacement, 80, of the substrate so that a first section, 61, of the curved profile of the elongated second electrode, 6, extends for a greater distance above a first section of the portion of substrate being treated than a second section of the portion of substrate being treated as the substrate and second electrode are being linearly displaced relative to each other. In particular, in this example, the first section extends for a greater distance along the same axis of displacement, 80, along which the substrate is moving, whereas the second section, 62, of the curved profile of the second electrode extends in a direction that is not in line with the axis of displacement and eventually extends in a direction that is generally perpendicular transverse to the linear direction of movement of the substrate, 8.

A first section of the substrate that passes between the electrodes and in particular, under this first portion, 61, of the electrode, 6, would therefore experience a greater residence time between the electrodes as the substrate is moved linearly in the first direction, 81, as compared to the section of substrate that passes under the second section, 62, of electrode, 6.

In the example shown in FIG. 5a, on the other hand, the electrodes are shaped and positioned relative to the axis of movement, 80 of the substrate, 8, passing underneath, so that the section of substrate that passes underneath the thick end, 64, of the wedge shaped electrode, 6c, 6d, as the substrate is moved linearly along the axis of movement, 80, has a greater residence time underneath the working electrode, 6c, than at the thin end, 65. This is because the thicker end of the wedge extends for a greater distance over the substrate than the thinner end of the wedge as the second electrode and substrate are being linearly displaced relative to each other. This is also the case for the embodiment shown in FIG. 5b, however, in this embodiment, the electrode is further shaped so that a first leading edge, 66, which, in this case, lies generally transversely or across the axis of movement, 80, when the substrate and/or second electrode is moving in the direction, 82, is curved, whereas the trailing edge, 67, is straight, (or vice versa if moving in the opposite direction, 81).

Therefore, this combination of providing a working electrode (or electrodes) that, due to its shape, can be positioned relative to the axis of displacement so that a first section of the substrate extends for a greater distance between the electrodes than a second section, results in a variation in residence time of the two sections of substrate between the two electrodes. As described herein, this may be due to the working electrode having a particular non-linear and/or non-uniform shaped cross sectional profile.

The examples shown in FIGS. 1 to 5 are therefore able to deliver a gradient type effect across the working area of a substrate. In these embodiments, the variation or gradient of surface condition or function is delivered in a system where the substrate to be treated moves linearly under a static working electrode, however, this may be other way round, as herein described. This means that multiple surface outcomes, chemistries, topographies and/or functionalities can be produced in a single sweep or step. This is in contrast to known technologies which are presently available, which may move a substrate in a linear direction of movement but use a linear elongated electrode to provide only a single outcome, i.e. a consistent condition across the surface of the substrate. In addition to this, due to the fact that the present invention utilises linear movement of the substrate, this allows for the possibility of scaling the process up to an increased capacity.

As can be seen in FIGS. 1 to 4, in some embodiments, at least a portion of the first electrode, 4, may extend in a first plane, (and since the substrate, 8, is provided on the upper surface, 14, of the first electrode, 4, so does at least a portion of the substrate, 8). In addition to this, at least a portion of the profile of the second electrode (which is facing the substrate) may extend in a second plane. In this example, this second plane is substantially parallel to the first plane (see FIGS. 2 and 4). It is, however, not absolutely essential that these planes are parallel to each other. In these embodiments, the working electrodes, 6, are therefore positioned relative to the platen, 4, to provide a reasonably constant gap (i.e. the electrode gap) between the electrodes during operation, as shown in FIGS. 2 and 4.

This is not essential, however, and in other embodiments, the electrode gap may be changed dynamically during or between the plasma treatments in order to create variations in the surface treatment. This can be achieved using a suitable mechanism such as that shown in FIG. 6, which shows a side view of an example of an embodiment of the system wherein a variable height adjustment feature is used as part of the assembly. This mechanism is capable of adjusting the working electrode height throughout the process. Although not shown in FIG. 6, this mechanism may be used with the embodiments described with reference to FIGS. 1 to 5, and the electrode(s) used in this variable height electrode arrangement may therefore be non-linear, curved, wedge-shaped or any other shape which may achieve the treatment effect described above. This mechanism for changing the electrode gap provides for a variation in the vertical height of the working electrode (and integrated gas distribution sub assembly) in an automated fashion either prior to the process or during the process. This enhances the efficiency in the production of even more variations of characteristics and functionality on the substrate surface through the plasma process, particularly when used in combination with the linearly moving substrate and/or electrodes as described herein.

FIGS. 6 to 15 show different ways by which the substrate, 8, and the working electrodes, 6, can be moved linearly in relation to each other. The features of the embodiments described with reference to FIGS. 1 to 5 may be used in conjunction with these methods. In some embodiments, the different shaped working electrodes may also be used together with any of these methods or systems.

As described above, the first electrode may itself comprise a platen, 4, which acts as a ground electrode, and the elongated second electrode may, in some embodiments, be a wire electrode that acts as a working electrode, 6, that is arranged at a distance above the platen, 4. The wire electrode and the platen are therefore positioned relative to each other, as described above, to provide a gap or space, 15, therebetween.

The features of the substrate, 8, are better seen in FIGS. 11 and 12 and it may further be described as having a first surface, 9, that is to be plasma treated, which faces the working electrode(s), 6, and a second, opposite, surface, 10, that is facing the platen, 4, on which it is positioned. Since, in the examples described herein, the gas distributor, 18, is provided at the working electrode, 6, it effectively provides gas between the upper surface, 9, of the substrate, 8, and working electrode(s), 6. It is therefore the upper surface, 9, of the substrate, 8, that is facing the working electrode(s) that is treated with the plasma.

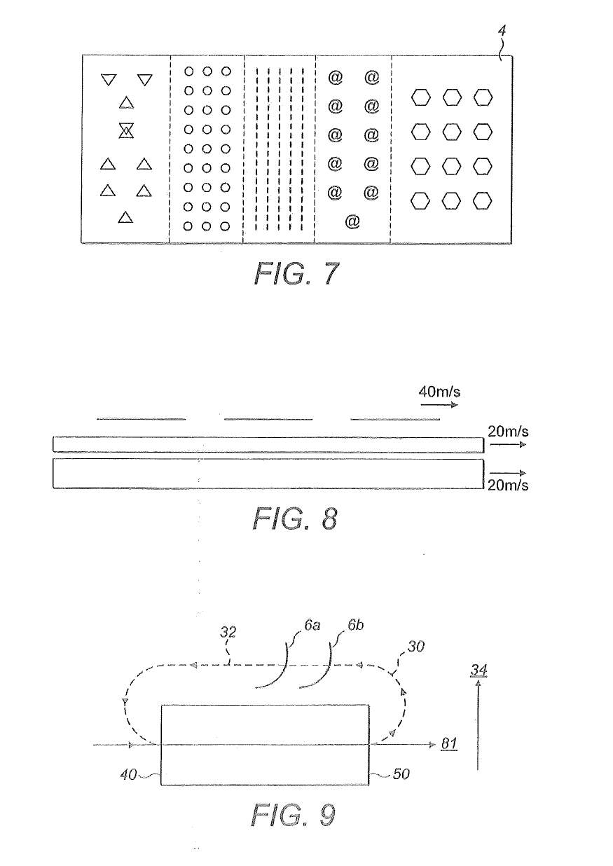

FIG. 7 shows a top view of an example of a platen electrode surface that comprises chemical or topological surface patterns. A dielectric material, 7, as described above, may be positioned over the platen electrode, 4, and may also, or alternatively, comprise such patterns. This feature of the invention provides for a variation in the localised condition of the plasma by varying the relatively tortuosity of the path for streaming high energy plasma components moving in the space, 15, between the electrodes, 4, 6. Physical or chemical variations in the insulation characteristics of the ground electrode assembly will produce localised electrical conditions and hence variation in the plasma condition, which will thereby exert a locally variable influence of the surface condition during processing. This provides a capacity for patterning on the surface of the substrate and a further increase in the capacity of the process to produce more surface function in a highly efficient manner.

FIG. 8 shows a side view of an embodiment of the invention wherein the ground electrode, 4, (platen), and the substrate, 8, provided thereon move in synergy, whilst the non-linear working electrode(s), 6, moves at a rate different to this. In one example, the ground electrode, 4, and substrate, 8, provided thereon, may move in a first linear direction, 81, at rate of 20 meters per second along the axis of movement, 80, whilst the electrode(s), 6, positioned above the substrate and working electrode, at least partially along the same axis of movement, 80, at a rate of 40 meters per second. Of course, other speeds could be used. Such a system, when used with the surface patterning feature of FIG. 7 would therefore allow the integrity of the pattern to be retained as generated on the substrate, during the linear movement of the different features.

FIG. 9 shows a top view of an example of an embodiment wherein the working electrodes, 6, are arranged on a carousel, 30, that is adapted to move the working electrodes, 6, so that they are moved in a loop from a position wherein they are above the first electrode, 4, and therefore also the substrate, 8, and so interfacing the platen, 4, and substrate, 8, (to thereby provide the gap, 15) to a position wherein they are no longer above the electrode, 4, or the substrate, 8, and so no longer interfacing the substrate, 8.

As can be seen in FIG. 9, the working electrodes, 6a, 6b, (and/or 6c to 6f) are moved via the carousel so that they are positioned, at some points in time, over the substrate and underlying platen, 4, at a first end, 40. This therefore creates a working area (i.e. the gap, 15), which is then present between the working electrode and the underlying ground electrode, or platen, 4. The substrate, 8 is provided within the gap, 15, as described above. The second electrodes, 6, are then moved by the carousel so that they travel over the substrate and underlying platen, 4, in the same direction, 81, as the direction in which the platen, 4, is moving. At some point, in time, the working electrodes may also move linearly over the substrate, as shown in the figures. Once the carousel has moved the electrodes, 6, across the length of the substrate, 8, and to/towards the second end, 50, of the substrate and/or platen, 4, then the carousel moves the electrodes away from the substrate and platen, 4, by moving the electrodes transversely away from the axis of movement, 80 and back into the loop before the process is repeated again. The carousel in this embodiment can therefore be described as moving in a plane that is generally parallel to the plane in which the substrate and/or platen, 4, extend.

In this embodiment, by making the working electrode(s), 6, mobile, the capacity of the system to produce multiple surface conditions in a more efficient way is therefore achieved. This function thereby provides the capacity to achieve variation in the treatment of the substrate without having to move the substrate during the treatment regime or alternatively to move the substrate at a velocity of choice during the process.

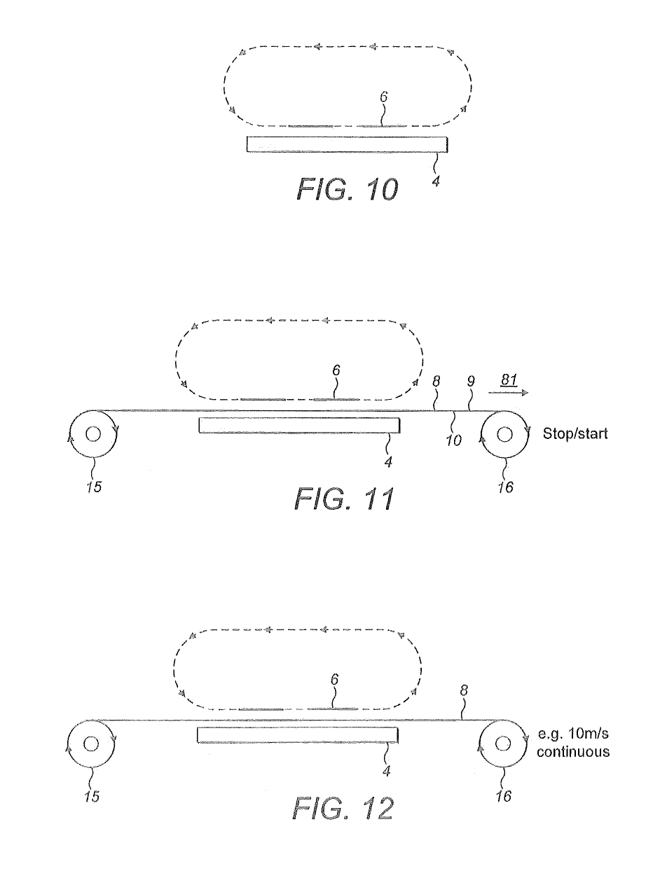

FIG. 10 shows a side view of a further embodiment of the invention which is similar in theory to that of FIG. 9, but where the carousel operates in a slightly different manner in that the rotation of the electrodes around the carousel occurs vertically away from the substrate and platen, 4, as opposed to laterally away from it.

In this embodiment, the carousel moves the electrodes, 6, (and gas distributor, 18, if provided thereon) in a plane that extends along the axis of movement, 80, and also perpendicular to the plane of the substrate and/or platen, 4. The lateral space consumed by the assembly of FIG. 9 can therefore be reduced by circulating the working electrode and/or gas distribution assembly in the vertical direction away from the working area.

These embodiments therefore show that different types of carousels having different orientations and circulating in different planes can therefore be used to move the electrodes, 6, and/or the gas distributor, 18, in a loop towards and away from the working area comprising the first electrode, 4, the second electrode(s) and the gap therebetween in which the substrate, 8, is positioned, as desired.

In these embodiments, the working electrode(s) are again shown as being non-linear and curved, however other shapes could be envisaged, as described above.

In contrast to the embodiments shown in FIGS. 1 to 4, in the embodiments shown in FIGS. 9 and 10, the substrate and underlying electrode, 4, or platen, are static whilst the carousel moves the working electrode and associated gas distributor towards and away from them.

In other embodiments, however, the substrate and first electrode, or platen, 4, do not have to be constantly static. FIG. 11 shows a side view of an example of an embodiment of the assembly wherein the platen, 4, is stationary, and the substrate, 8, is moved intermittently and linearly in the direction, 81. In this embodiment of the present invention, the working electrode(s), 6, and/or associated gas distribution assembly may be rotated about a loop by the carousel in the same way as in FIG. 9 or 10, for example, whilst at least the substrate, 8, is moved intermittently in the same direction, 81, as the working electrode, 6. The substrate, 8, may be moved in the linear direction, 81, by different means, however, in this example, it is moved from a first reel, 15, to a second reel, 16. In this embodiment, the rollers, 15, 16, are stopped and started, so that the linear movement of the substrate, 8, in the first direction, 81, is also intermittent and stops and starts accordingly, whereas the working electrodes, 6, are moved around the carousel continuously. In this embodiment, the substrate to be treated with gradient surface functionality is therefore mounted and transferred through the process in a start/stop fashion.

Due to this, the capacity to deliver the variation in localised plasma condition can therefore be controlled solely by the movement of the working electrode and/or associated gas assembly, but the substrate can be delivered to be treated on a reel to reel format. This means that, although the substrate can be moved, the present invention is not limited to the movement (or continuous movement) of the substrate and can be delivered using such a start-stop regime.

FIG. 12 shows a side view of an example of an embodiment of an assembly similar to that in FIG. 11, except that the substrate to be treated with gradient surface functionality is mounted and transferred through the process in a continuous fashion using a form of a reel to reel mechanism. In other words, both the substrate, 8, as well as the overhead working electrode assembly are moving continuously. The speeds of the working electrode, 6, and gas distributor assembly, 18, may be ratioed to the speed of movement of the substrate, at least when the working electrodes, 6, are passing over the working area, i.e. over the substrate and underlying electrode, 4.

Due to this, the efficiency and/or the efficacy of the process may be improved by moving the working electrode and/or gas distribution assembly, 18, and the substrate, 8, at ratioed speeds at least through the working or processing zone or area (i.e. when the working electrodes are passing over the first electrode to provide the gap, 15).

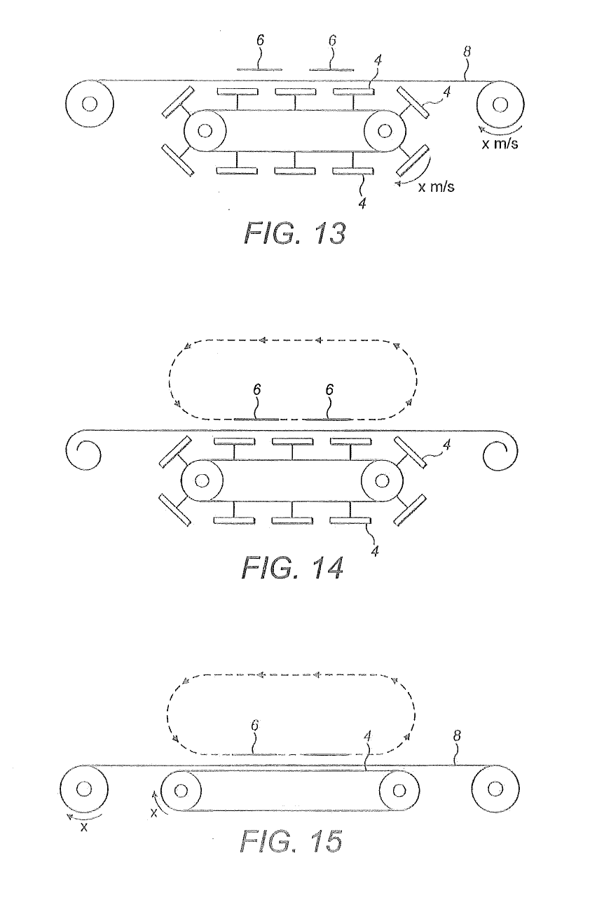

In some situations, it may be necessary to use a solid ground electrode or platen, 4, that does not move relative the substrate, 8. In such a situation, an embodiment of the present invention allows this by providing a carousel assembly that comprises a plurality of individual platens, 4. FIG. 13 shows a side view of an example of this where the ground electrode, 4, takes the form of many inflexible platen type elements, 4, mounted on a carousel that cycles so as to match the speed of transition of the substrate, 8, between the electrodes, 4, 6. In this embodiment, the non-linear working electrodes positioned above the substrate, 8, are stationary. This embodiment therefore builds on the embodiments wherein a solid platen is used as the ground electrode and shows how the invention can be used to deliver a large capacity in a continuous process environment.

FIG. 14 shows a side view of an example which is similar to that shown in FIG. 13, however, instead of being stationary (as in FIG. 13), in this example, the working electrode and ground electrode are moved simultaneously on speed ratioed carousels. This embodiment therefore builds on that shown in FIG. 13 to provide an improvement in the range of outcomes or speed of processing to be delivered in a situation wherein a stationary working electrode would have limited the speed that the reel to reel assembly could effectively move the substrate through the process.

FIG. 15 shows a side view of an example of an embodiment which is similar to that of FIGS. 13 and 14 but wherein the ground electrode is flexible in nature and may be continuously cycled through the process. The flexible ground electrode can be used to deliver an appropriate effect in processing where the electrical characteristics are suitable. In this embodiment, this can be used to produce a surface on the substrate that relates to localised conditions found on the flexible ground electrode. In a further embodiment, which is not shown, the system of FIG. 15 may be used in combination with the patterned dielectric/ground electrode surface characteristic shown in FIG. 6.

For example, if the flexible ground electrode has localised variations, and if the speeds of the substrate, 8, end flexible first electrode, 4, are the same, the surface outcome can also be localised on the substrate, 8. Alternatively, if the relative speed of the ground electrode is significantly different to the substrate speed, the process could be used to deliver outcomes on the substrate with a very small degree of variation, as the differences produced on the substrate by small localised variations in the ground electrode condition could be averaged out by its constant relative movement.

In a situation wherein the production of a defined pattern is important, the flexible ground electrode and the substrate can be moved at the same speed. Alternatively, or additionally, it may be beneficial to move the patterned ground electrode at a ratioed speed to the substrate in order to deliver a specific patterned outcome on the surface of the substrate. Highly defined localised variations can therefore be produced in a reel to reel set up using a flexible ground electrode mechanism. Defined offsets (delivered through ratioed speed) of the underlying pattern can be used to deliver alternative (overlaid) patterns on the substrate.

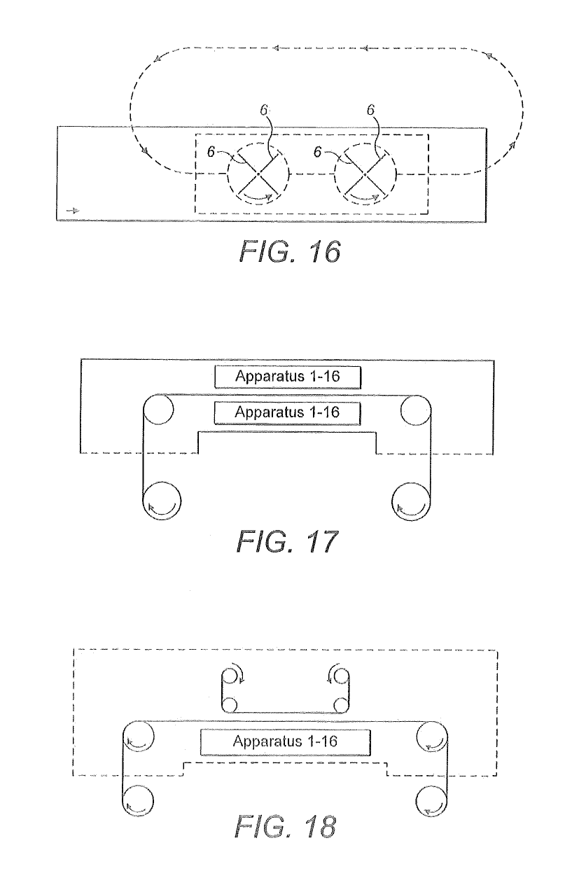

FIG. 16 shows a top view of an example of another embodiment of the invention which may use the types of working electrodes (such as non-linear, curved, wedge shaped etc) described above with reference to FIGS. 1 to 5, or may alternatively use different types of working electrode.

In the embodiment shown in FIG. 16, the substrate, 8, is being moving linearly along the axis of movement, 80, as described above. At the same time, the working electrodes, 6, are also being moved linearly in the same direction, 81, and then transversely away from the substrate surface, as in the example shown in FIG. 9. In this example, however, instead of the carousel moving each individual working electrode, 6, in a loop, a rotating electrode assembly, or plurality of rotating electrode assemblies (each assembly comprising a plurality of electrodes) are mounted on the carousel and these are then moved around the loop, as in the example shown in FIG. 9, whilst the electrode assemblies rotate.

These electrode assemblies therefore rotate about their own individual axis of rotation as well being moved around the loop of the carousel, 30. The rotation is limited in this instance to the dimensions of the elongated electrode in order to provide the variation in residence time between the electrodes and associated variation in surface characteristics. In some embodiments, the elongated electrodes may be linear, and in others they may be non-linear.

This embodiment therefore provides a variation in the localised conditions of the plasma and the plasma residence time at specific positions on the substrate via a rotation of the electrode and/or gas distribution assembly. As mentioned above, this system and method may be used with working electrodes, that have a linear profile, (such as those described in WO 2012/107723 A1) or alternatively may be used in conjunction with the electrodes described above which may have curved, or non-linear, or non-uniform profiles or cross sections.

The invention may also be carried out using any of the different movement methods, speeds, ratios, variations etc as described above and is not limited to the feature of both the substrate and the working electrodes being moved along the axis of movement. For example, it may be carried out in the manner described with reference to FIGS. 1 to 4, i.e. by moving only the substrate (and/or platen) linearly between the first and second electrodes and keeping the electrode assemblies above stationary, whilst they rotate above about their own central axes.

Alternatively, the substrate may be stationary whilst the electrode assemblies are moved linearly above, as in FIGS. 9 and 10. The different mechanisms of carousel described herein could also be used in conjunction with this embodiment of the invention. The different speeds, ratios, and types and variations of ground electrode, for example, may also be used in combination with this embodiment.

FIG. 17 shows a side view of an example of an embodiment of the assembly of any of the previous assemblies operating in a gas capture environment, i.e. closed off at high points to capture/retain low density gases and remove heavier gases from the processing environment. This arrangement may be inverted to capture high density gases for the process.

FIG. 18 shows a side view of an example of an embodiment of the assembly of any of the previous assemblies where the elongated electrode is replenished continuously or on a start/stop basis.

In a further embodiment of the invention, shown in FIG. 11, the substrate can alternatively be delivered continuously and the speed at which the substrate moves differs from the speed at which the working electrode moves.

In one embodiment, the working electrodes may move at a speed that is twice that of the substrate, 8, positioned underneath, as in FIG. 7. Alternative speeds may also be used.

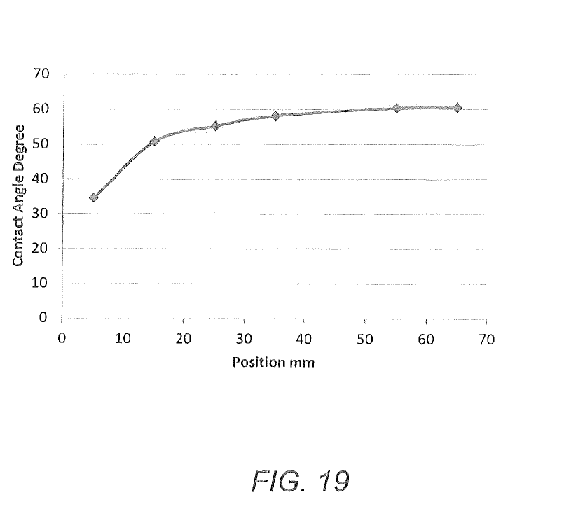

FIG. 19 shows an example of a type of variation surface condition that can be delivered using the processes described here. Water contact angle data is shown for a polypropylene substrate modified by plasma processing with novel electrode configuration. Here, the area of the substrate closer to the origin point has been subjected to a greater plasma exposure as associated with the electrode configuration resulting in a more hydrophilic surface condition. This effect is less pronounced moving to positions of progressively lower and less different plasma exposure where adjacent conditions are very alike.

The present invention described herein therefore provides a novel and inventive way in which the conditions between the electrodes comprise those required for creation and control of a plasma with a dielectric barrier discharge plasma shown as an example. In dielectric barrier discharge, the key elements are the electrodes, the characteristics of the electrical discharge created in the form of micro-streamers (or glow-like plasma under suitable conditions) and the composition of the gas that makes up the dielectric gap between the electrodes. The actual plasma conditions are largely determined by the dielectric properties which is a consequence of the nature of the gas (air or other gas) that the discharge passes through. It is typical in dielectric barrier discharge for a solid insulating material to sheath one or other or both of the electrodes. The figures do not show the sheathing barrier material, as the invention described here can also be applied in non-dielectric barrier discharge applications and as such the applications should not be limited to such an arrangement alone.

The electrode assemblies described herein may be configured in a way so as to achieve effective masking of the discharge in specified zones of the substrate in order to achieve localised or varied treatment in such specific regions.

The preferred embodiment has the capacity to control the discharge so as to operate in various gas and gas mixture environments. This may provide the facility to produce layered treatment effects on the substrate surface indicated above. For example, a surface roughness may be induced via treatment using selected gas mixtures and discharge parameters suited to deliver an ablative treatment effect. Likewise, chemical functionalities may be grafted to the surface in succession using selected gas/vapour/aerosol and surface liquid/gel mixtures and appropriate discharge parameters. Further ablative treatment may then be used to expose other chemistries and appropriate surface roughness. It is typical with atmospheric pressure plasma treated surfaces for ageing to affect the chemical functionality and related properties such as wettability. As such, further functions of the substrate surface character would relate to the time elapsed since processing.

As has been described above, by providing a high voltage plasma and varying substrate transit speed through the plasma region, varying gas concentration in the plasma region or varying gas flow control across the plasma region, controlled and repeatable changes in surface chemistry, topography, morphology of the substrate can be provided.

The present invention is not limited to the electrode and chamber/enclosure dimensions, gases, flow rates, flow distribution dynamics, power levels, or cycle numbers provided in the examples above and this data provides only examples of the potential surface outputs in terms of chemical concentrations and production of surface gradient effects. In addition to changing the overall chemical composition, the type and nature of surface chemical bonds involved can be controlled using the system. Determination of the subtle changes to surface properties that occur over the macro-scale, can provide useful data to predict subsequent interfacial responses.

If used with a plasma reactor chamber, this may be an enclosed chamber which can be stand alone or integrated with a given manufacturing/treatment process. A pre-treatment chamber environment may also be created to deliver gas/vapour concentrations and to control operational conditions such as humidity and temperature. Whereas, the normal operation of the process is at or near atmospheric pressure, the ambient environment can be over- or under-pressurised up to the limit of the conditions necessary for creation of the plasma discharge.

In some embodiments, the substrate or other device supporting the substrate may be clamped within a frame that interfaces with either the working electrode, the dielectric layer or the grounded electrode, thereby providing for accurate location within the system and physical separation of the electrode/dielectric layer from the gas gap/discharge region. The flow conditions and content of the gas used to provide the chamber with a general background environment may be different from that of the gas used during the plasma treatment process.

The plasma and/or gas flow may be monitored and controlled via feedback from electrical, spectroscopic and residual gas analysis techniques.

A secondary or multi-treatment processing stage may be carried out in order to homogeneously or heterogeneously deposit and/or polymerise monomers and/or oligomers using other forms of plasma or related processing or using the above gradient technology.

In some embodiments, the substrate may be arranged on a secondary material of known chemistry having elements and/or functionalities that would be useful when transferred to the substrate. Both the substrate and substrate holder may then be subjected to the plasma so as to transfer some of the chemical moieties from the secondary material to the substrate surface in the process.

As noted previously, this processing treatment typically extends nanometres into the substrate surface region with the actual extent of substrate modification and the chemical composition within this modified region/depth being gradated. The nature of this gradual change in properties into the substrate surface is a function of a number of parameters including the plasma conditions adjacent to the surface. It may also be affected by exposure to the atmosphere present after processing. Therefore, control of post-processing conditions may be necessary.

Surface chemical gradients are useful in a large range of industries and areas of research. For example, the present invention may be useful in surface technologies such as adhesion, coating, printing, smart packaging, painting, plasma treatment, etching, deposition, MEMS, electroplating, electroless plating, optics, polishing, anti-corrosion, anti-fouling, cleaning, laser surface texturing, laser ablation, sputtering, embossing/moulding, self assembled monolayers, electrospinning, spincoating, drug development, catalysis, fuel cell, solar cell, semiconductor, pharmaceuticals, diagnostics, and medical device manufacturing.

The invention may also be useful in the broad area of biomedical engineering and may be applied to laboratory equipment, products and supplies, biomaterials, biocompatible coatings/implants, tissue engineering, in vitro diagnostics, chemo-, immuno-, monoclonal antibody and vaccine therapies in oncology, genetics, bioinstrumentation, nanofabrication, cardiac mapping, wound healing, regenerative medicine, micro and nanoscale devices and nanoscale metrology and analysis. The substrates could be supplied to users with tray frame sets, specialised autoclavable tray frame sets, multi-well/channel substrates and various forms of multiple test devices.

It is important to note that the surface treatment process disclosed here can provide a mechanism by which advanced processes which are dependent on effects that occur in the sub-micron to nanoscale dimension can be used commercially. In this regard, the system may be well suited to alignment with products, companies and markets in the microscopy and spectroscopy fields noted previously, where the technology offering is surface specific.

It should also be noted that whilst the type of atmospheric pressure plasma used in the system reported here is dielectric barrier discharge, the principle involved applies to all atmospheric processing conditions and those that operate at close to a normal atmosphere state. The terms dielectric barrier discharge and atmospheric pressure plasma are often used interchangeably and should be considered as such in this disclosure without being seen as a limiting factor in the types of plasma that can be covered and protected as part of the process.

WO 2012/107723 describes a label which is configured to produce an image that varies over time. In some embodiments, the image changes colour when it contacts one or more types of gas or vapour. In some embodiments, functional aspects of the label may be produced using plasma processing. The present invention can therefore be used to implement the technologies disclosed in this document. This allows for providing a large scale plasma process that is capable of producing time dependent labels in significant numbers and rapidly.

1.-54. (canceled)

55. A system for modifying a substrate using a plasma, comprising:
a first electrode and a second electrode disposed within a chamber;
a mechanism for supporting at least a first portion of a substrate to be treated between said first and second electrodes;
means for supplying one or more gases between at least the second electrode and the substrate;
means for supplying a voltage to at least one of the electrodes so as to create a plasma discharge between the second electrode and the substrate;
means for moving the substrate and/or said second electrode so that said substrate and said second electrode are linearly displaced relative to each other along an axis of displacement during movement; and
rotating either the substrate or at least one of the electrodes about an axis of rotation during said relative linear movement, so that a first section of the portion of substrate has a greater residence time between the electrodes than a second section of said portion of substrate.

56. The system of claim 55, wherein said second electrode has a shape configured to cause said first section of the portion of substrate to have said greater residence time between the electrodes during said linear displacement than said second section of said portion of the substrate and/or said shape configured to cause said first section of the portion of substrate to extend for a greater distance between said first and second electrodes along said axis of displacement than said second section of said portion of substrate.

57. The system of claim 55, wherein said second electrode comprises a first side with a first shaped profile, and wherein said substrate is positioned between said electrodes so that said first shaped profile is facing said portion of substrate positioned between the electrodes.

58. The system of claim 55, wherein at least a portion of the first electrode extends in a first plane and at least a portion of the second electrode extends in a second plane, wherein said first and second planes are substantially parallel to each other and thereby define a gap between these substantially parallel portions, and wherein said substrate is configured to pass through the gap during said linear movement of said substrate and/or said second electrode.

59. The system of claim 55, wherein said first electrode comprises one or more platens and said substrate is provided on said one or more platens, such that movement of said one or more platens having said substrate provided thereon causes movement of said substrate and said linear displacement of said substrate and said second electrode relative to each other.

60. The system of claim 59, wherein said one or more platens are provided on a platen carousel such that rotating said carousel causes said linear displacement of said substrate and said second electrode relative to each other, said platen carousel being configured to rotate in a plane that extends along the axis of displacement and also perpendicular to the plane of the substrate and/or platen, to thereby move said one or more platens linearly along said axis of displacement.

61. The system of claim 55, wherein said substrate extends from a first reel to a second reel and wherein substrate and said second electrode are linearly displaced relative to each other by rotating said first and/or second reel to thereby move said substrate along the axis of displacement.

62. The system of claim 55, wherein said second electrode is mounted on an electrode carousel configured to rotate in a plane that extends along said axis of displacement and also perpendicular to the plane of the substrate and/or platen, to thereby move said second electrode along said axis of displacement.

63. The system of claim 55, wherein said second electrode comprises a wire electrode, a tubular electrode, or a rod electrode and/or wherein the first electrode and/or second electrode is covered in an electrical insulator.

64. The system of claim 55, wherein the one or more gases are supplied at different flow rates, and/or at a plurality of loci between the electrodes.

65. The system of claim 55, wherein a gas distributor is configured to supply the one or more gases to the region between the electrodes in a non-uniform manner, the gas distributor comprising an elongated conduit having a plurality of apertures arranged along its length and located such that the one or more gases exit the conduit through the apertures into the region between the first and second electrodes.

66. The system of claim 65, wherein the second electrode comprises the gas distributor and is configured as an elongated tube having apertures.

67. The system of claim 55, wherein a plurality of said first electrodes and/or a plurality of said second electrodes are disposed such that different, separate regions of said substrate pass between the first and second electrodes simultaneously.

68. The system of claim 55, wherein the surface of said first or second electrode, or the surface of a dielectric material covering said first or second electrode, comprises a chemical or topological pattern thereon.

69. The system of claim 55, wherein at least one of the electrodes has a conduit and one or more apertures extending from the conduit to the outside of the electrode and said one or more gases are supplied through the conduit so that the one or more gases flow out of the at least one electrode through a plurality of apertures.

70. A method of modifying a substrate using a plasma, comprising:
providing a first electrode and a second electrode within a chamber;
arranging the substrate such that a portion of the substrate is between the electrodes;
supplying a voltage to at least one of the electrodes so as to create a plasma discharge between the electrodes which contacts at least said portion of the substrate;
moving either the substrate and/or said second electrode such that said substrate and said second electrode are being linearly displaced relative to each other along an axis of linear displacement during said movement; and
rotating either the substrate or said second electrode about an axis of rotation during said relative linear displacement along said axis, so that a first section of the portion of substrate has a greater residence time between the electrodes than a second section of said portion of substrate.

71. The method of claim 70 further comprising providing one or more electrode assemblies comprising a plurality of said second electrodes and rotating said plurality of said second electrodes about said axis of rotation.

72. The method of claim 70, comprising moving said substrate linearly at a first speed along said axis of displacement and moving said second electrode at a second speed along said axis of displacement, said first and second speeds being different to each other, such that said portion of said substrate passes along said axis between the electrodes.

73. The method of claim 70, comprising applying a potential difference or a current to the electrodes so as to generate the plasma therebetween, such that the magnitude of the current or potential difference is varied with time.

74. The method of claim 70, further comprising supplying one or more gases to the region between the electrodes, at least one of the one or more gases comprising or carrying at least one type of chemical which modifies the substrate when the plasma is being generated.

75. The method of claim 74, further comprising varying the flow rate of the one or more gases into the region between the electrodes across the substrate or varying the flow rate through different apertures in a gas distributor.

76. The method of claim 70, wherein modifying the substrate comprises using the plasma treatment to alter the surface chemistry, topography, or morphology of the substrate surface, preferably by different amounts in different areas of the substrate, the plasma treatment being applied at or about atmospheric pressure.

77. The method of claim 70, wherein modifying the substrate comprises using the plasma to alter the substrate by way of any one or more of the following processes: modifying the substrate surface to include chemical functionalities; depositing monomers or oligomers on the surface; grafting monomers or oligomers on the surface; polymerising monomers or oligomers on the surface; or changing the surface roughness of the substrate, the plasma treatment being applied at or about atmospheric pressure.

78. The method of claim 70, further comprising replenishing the first and/or second electrode after having been subjected to said plasma.

79. The method of claim 70, wherein supplying the voltage further comprises generating the plasma by way of a dielectric barrier discharge process.

80. The method of claim 70, further comprising supplying one or more gases to the region between the electrode and the substrate through a plurality of apertures such that the one or more gases have different flow rates through different apertures.

81. The method of claim 70, further comprising vacuum forming the modified substrate so as to provide a 3-dimensional surface form.

82. The method of claim 70, further comprising processing the substrate after having exposed it to said plasma, said processing being by one or more of the following techniques: embossing, vacuum forming, lithography, injection moulding, sputtering, chemical treatment (e.g. using silane derivatives), biomaterial deposition, laser ablation, dip coating, spin coating, deposition, spraying, coating, ion beam etching, punching, cutting, mounting, adhering, welding, mechanically fixing or housing in substrate carriers.
